(19) United States
(12) Patent Application Publication
(10) Pub. No.: US 2013/0056691 A1
(43) Pub. Date: Mar. 7, 2013

(54) Metal Oxide Semiconductor Films, Structures, and Methods

(71) Applicant: Moxtronics, Inc., Palatine, IL (US)

(72) Inventors: Yungryel Ryu, Columbia, MO (US); Tae-Seok Lee, Columbia, MO (US); Henry W. White, Columbia, MO (US)

(73) Assignee: Moxtronics, Inc., Palatine, IL (US)

(21) Appl. No.: 13/660,293

(22) Filed: Oct. 25, 2012

Related U.S. Application Data
(63) Continuation of application No. 12/711,696, filed on Feb. 24, 2010.
Application No. 12/711,696 is a continuation of application No. 11/394,382, filed on Mar. 29, 2006, now abandoned.
Application No. 11/394,382 is a continuation-in-part of application No. 10/525,611, filed on Sep. 12, 2005, now Pat. No. 7,824,955.
(60) Provisional application No. 60/666,453, filed on Mar. 30, 2005.
(60) Provisional application No. 60/406,500, filed on Aug. 28, 2002.

(51) Int. Cl. H01B 1/08; C01B 19/00; C01G 9/02

(52) U.S. Cl. 252/519.4; 423/594.14; 423/508; 252/519.51

(57) ABSTRACT

Materials and structures for improving the performance of semiconductor devices include ZnBeO alloy materials, ZnCdOSe alloy materials, ZnBeO alloy materials that may contain Mg for lattice matching purposes, and BeO material. The atomic fraction x of Be in the ZnBeO alloy system, namely, Zn₁₋ₓBeₓO, can be varied to increase the energy band gap of ZnO to values larger than that of ZnO. The atomic fraction y of Cd and the atomic fraction z of Se in the ZnCdOSe alloy system, namely, Zn_{1-y}Cd_{y}O_{1-z}Se_{z}, can be varied to decrease the energy band gap of ZnO to values smaller than that of ZnO. Each alloy formed can be undoped, or p-type or n-type doped, by use of selected dopant elements.

### CROSS-REFERENCE TO RELATED APPLICATIONS INCORPORATION BY REFERENCE

This patent application is a Continuation of U.S. Ser. No. 11/394,382 filed Mar. 29, 2006, which claims the priority benefit of provisional 60/666,453 filed Mar. 30, 2005. Patent application Ser. No. 11/394,382 is also a CIP of U.S. Ser. No. 10/525,611 filed Sep. 12, 2005, which is a U.S. National Stage filing of PCT/US03/27143 filed Aug. 27, 2003, which in turn claims the priority benefit of U.S. 60/406,500 filed Aug. 28, 2002. Each of the foregoing is incorporated by reference herein in its entirety.

### FIELD OF THE INVENTION

The present invention relates to zinc oxide based alloy semiconductor materials, and in particular, to such materials that can be fabricated with a range of desirable energy band gap values. Such semiconductor materials can be used to fabricate semiconductor layers, structures and devices and to improve the function and performance of semiconductor devices.

### BACKGROUND OF THE INVENTION

The optical properties of zinc oxide (ZnO) have been studied for its potential use in semiconductor devices, in particular for photonic light emitting devices such as light emitting diodes (LEDs) and laser diodes (LDs), and photonic detectors such as photodiodes. The energy band gap of ZnO is approximately 3.3 electron volt (eV) at room temperature, corresponding to a wavelength of approximately 376 nanometer (nm) for an emitted photon of this energy. Light emission has been demonstrated from ZnO LEDs using p-type and n-type materials to form a diode. ZnO has also been used to fabricate a UV photodetector and a field effect transistor (FIT).

ZnO has several important properties that make it a promising semiconductor material for optoelectronic devices and applications. ZnO has a large exciton binding energy, 60 meV, compared with 26 meV for GaN and 20 meV for ZnSe. The large exciton binding energy for ZnO indicates promise for fabrication of ZnO-based devices that would possess bright coherent emission/detection capabilities at elevated temperatures. ZnO has a very high breakdown electric field, estimated to be about 2×10⁶ V/cm (>two times the GaAs breakdown field), indicating thereby that high operation voltages could be applied to ZnO-based devices for high power and gain. ZnO also has a saturation velocity of 3.2×10⁷ cm/sec at room temperature, which is larger than the values for gallium nitride (GaN), silicon carbide (SiC), or gallium arsenide (GaAs). Such a large saturation velocity indicates that ZnO-based devices would be better for high frequency applications than ones made with these other materials.

Still further, ZnO is exceptionally resistant to radiation damage by high energy radiation. Common phenomena in semiconductors caused by high-energy radiation are the creation of deep centers within the forbidden band as well as radiation-generated carriers. These effects significantly affect device sensitivity, response time, and read-out noise. Therefore, radiation hardness is very important as a device parameter for operation in harsh environments such as in space and within nuclear reactors.

From the perspective of material radiation hardness, ZnO is much better suited for space operation than other wide bandgap semiconductors. For example, ZnO is about 100 times more resistant than is GaN against damage by high-energy radiation from electrons or protons.

ZnO also has a high melting temperature, near 2000° C., providing possibilities for high temperature treatments in post-growth processes such as annealing and baking during device fabrication, as well as for applications in high temperature environments.

Large-area ZnO single crystal wafers (up to 75 mm diameter) are commercially available. It is possible to grow homo-epitaxial ZnO-based devices that have low dislocation densities. Homo-epitaxial ZnO growth on ZnO substrates will alleviate many problems associated with hetero-epitaxial GaN growth on sapphire, such as stress and thermal expansion problems due to the lattice mismatch.

ZnO has a shallow acceptor level, 129 meV, compared with 215 meV for GaN. The low value for the acceptor level means that p-type dopants in ZnO are more easily activated and thereby help generate a higher hole concentration in ZnO than the corresponding hole concentration in GaN for the same dopant level concentration in each material. ZnO-based devices can be fabricated by a wet-chemical etching process. These properties make ZnO a most attractive material for development of near- to far-UV detectors, LEDs, LDs, FETs, and other optoelectronic devices.

It would be desirable to modify the energy band gap of ZnO to smaller values than that for ZnO and also to larger values than that for ZnO in order to provide for increased function, capability and performance of semiconductor devices.

As examples, a material with band gap energy larger than that of ZnO would allow for emission at shorter wavelengths for LED and LD devices. Correspondingly, a material with band gap energy smaller than that of ZnO would allow for emission at longer wavelengths for LED and LD devices.

Materials with larger band gaps would allow fabrication of semiconductor heterostructures such as active light emitting layers, quantum wells, multiple quantum wells, superlattices, cladding layers, absorption layers, transmission layers, and photodetectors that have increased function, capability and performance in the ultraviolet (UV) region of the spectrum. Such devices and capabilities include LEDs and LDs that emit in the UV region of the spectrum and UV photodetectors for solar blind and other applications.

Materials with smaller bandgaps would allow fabrication of semiconductor heterostructures such as active light emitting layers, quantum wells, multiple quantum wells, superlattice layers, cladding layers, absorption layers, transmission layers, and photodetectors that have increased function, capability and performance in the visible region of the spectrum.

Such devices and capabilities include LEDs and LDs that emit in the visible region of the spectrum and visible photodetectors.

Semiconductor devices fabricated from ZnO based materials that can operate with increased performance, capability and function are desirable for use in many commercial and military sectors including, but not limited to devices and areas such as light emitters, photodetectors, FETs, PN diodes, PEN diodes, NPN transistors, PNP transistors, transparent transistors, circuit elements, communication networks, radar, sensors and medical imaging.

Accordingly, it would be useful to provide ZnO based semiconductor materials that can be tailored to have specific energy band gap values.

By way of particular example in connection with the present invention, it would be useful to provide a ZnO based semiconductor material that can be tailored to have specific energy band gap values by adjusting the atomic fraction of Be in a ZnBeO semiconductor alloy.

It would also be useful to provide ZnO based semiconductor materials that can be tailored to have specific energy band gap values by adjusting the atomic fraction of Cd and the atomic fraction of Se in a ZnCdOSe semiconductor alloy.

### SUMMARY OF THE INVENTION

The invention addresses the above-described needs, by providing materials for improving the performance of semiconductor devices, including ZnBeO alloy materials, ZnCdOSe alloy materials, ZnBeO alloy materials that may contain Mg for lattice matching purposes, and BeO materials.

The atomic fraction x of Be in the ZnBeO alloy system, namely, Zn₁₋ₓBeₓO, can be varied to increase the energy band gap of ZnO to values larger than that of ZnO.

The atomic fraction y of Cd and the atomic fraction z of Se in the ZnCdOSe alloy system, namely, Zn_{1-y}Cd_{y}O_{1-z}Se_{z}, can be varied to decrease the energy band gap of ZnO to values smaller than that of ZnO.

Each alloy formed can be undoped, or p-type or n-type doped, by use of selected dopant elements.

These alloys can be used alone or in combination to form active photonic layers that can emit over a range of wavelength values, heterostructures such as single and multiple quantum wells and superlattice layers or cladding layers, and to fabricate optical and electronic semiconductor devices.

These structures can be applied to improve the function, capability, and performance of semiconductor devices.

Other embodiments, examples, features and aspects of the present invention will also be disclosed herein.

The foregoing description and other objects, advantages, and features of the invention and the manner in which the invention is accomplished will become more apparent after considerations of the following detailed description of the invention taken in conjunction with the accompanying drawings.

### BRIEF DESCRIPTION OF THE DRAWINGS

Further understanding of the present invention is provided by the following Detailed Description read in connection with the attached drawing figures, in which:

FIG. 1 is a schematic showing a film of ZnBeO alloy that has been deposited on a single crystal sapphire substrate using, by way of example, the HBD process for film growth (and by analogy, structures for other Zn based allows such as those using Cd and/or Se).

FIG. 2 shows data for examples of a ZnBeO embodiment of the invention, with transmittance plotted versus wavelength of light incident on the ZnBeO alloy films, and also for a ZnO film.

### DETAILED DESCRIPTION OF THE INVENTION

Overview and Terms Used in this Document:

The present invention relates to zinc oxide based alloy semiconductor materials that can be fabricated with a range of desirable energy band gap values, and which can be used to fabricate semiconductor structures and devices, and to improve the function and performance of semiconductor devices. To facilitate understanding of the invention, we first provide a discussion of terms utilized in connection with describing the invention, which include the following:

The active layer of a LED or LD relates to the semiconductor layer from which light is emitted. Electrical carriers of n-type or p-type conductivity combine in the active layer. The value of the energy band gap determines the wavelength of the characteristic light emission.

A quantum well (QW) structure or a multiple quantum well (MQW) structure is comprised of a layered semiconductor structure with one or more layers having a smaller energy band gap than one or more neighboring layer or layers so that n-type carriers and p-type carriers are more probable to be located in the layer or layers with smaller energy band gap. The characteristic wavelength of photonic emission will be that determined by the semiconductor material with smallest energy band gap in a QW or MQW.

A super lattice (SL) structure is comprised of first layers and second layers of semiconductor material having different energy band gap values and wherein each first and second layer is sufficiently thin that it can strain if necessary to form an epitaxial layer with adjacent layers and wherein the first and second layers may have different concentrations of n-type dopant elements or may have different concentrations of p-type dopant elements. Use of a SL layered structure in lieu of a thick layer of uniform composition can be used to fabricate more efficient devices by reducing strain that may be created by use of a thick layer of a semiconductor material of uniform composition.

Various designs for epitaxially layered structures have been proposed in the prior art to increase performance of semiconductor devices such as LEDs and LDs. Among these structures are semiconductor heterostructures that are comprised of alternate layers of materials that have different energy band gaps. Such heterostructures include but are not limited to quantum wells, multiple quantum wells, superlattice layers, isolation layers, light reflecting films and multilayers, metal contact layers, cladding layers and substrates.

For example, heterostructures and adjacent epilayers that employ GaN-based semiconductor materials with different energy band gaps have been described or proposed to modify the properties of light emitting semiconductor devices.

The lower limit for the wavelength emitted by an LED or LD can be made smaller by increasing the value of the energy band gap of the active layer in which light emission occurs. In accordance with the present invention as further described below, the energy band gap of ZnO can be increased by alloying ZnO with a suitable material using a suitable growth method.

The upper limit for the wavelength emitted by an LED or LD can be made larger by decreasing the value of the energy band gap of the active layer in which light emission occurs. In accordance with the invention as further described below, the energy band gap of ZnO can be decreased by alloying ZnO with a suitable material using a suitable growth method.

“Band gap modulation” and “band gap engineering” are terms used herein in connection with the present invention, to changing the band gap of a material to either increase or decrease the value of the energy band gap.

In accordance with the invention, band gap modulation can be used to increase photon and carrier confinement in a semiconductor device. Band gap modulation can be used to tailor the wavelength of light emission in a light emitting semiconductor device and to improve the response characteristics of a photodetector semiconductor device.

Prior art documents have discussed increasing the energy band gap of ZnO to 3.99 eV at room temperature by alloying ZnO with magnesium (Mg) to form ZnMgO; namely, Zn_{1-w}Mg_{w}O. As the content of Mg was increased up to w=0.33, the energy band gap was increased to 3.99 eV. Heterostructures were fabricated by using ZnO and ZnMgO layers. However, a crystal phase separation occurs between MgO and ZnO if the Mg-content exceeds the value corresponding to w=0.33 due to the different crystal structure between ZnO and MgO and large difference in lattice constants. MgO has a cubic lattice structure with lattice spacing 0.422 nm, whereas ZnO is hexagonal with 0.325 nm. Therefore, ZnMgO alloys have limited utility, for increasing the energy band gap in semiconductor devices up to 3.3 eV but not to larger energy band gap values.

It is contemplated that further work in this area will lead to an increase in the band gap to values larger than approximately 3.3 eV in order to fabricate semiconductor devices that can operate at short wavelengths. For simplicity of growth, it would be desirable to have an alloy system comprised of one set of elements to cover the energy band gap range from approximately 3.3 eV to an energy band gap value of approximately 10.6 eV, corresponding to a wavelength of approximately 117 nm. The present invention, as described in greater detail below, enables such an alloy system.

Beryllium oxide (BeO) has an energy band gap of approximately 10.6 eV at room temperature, corresponding to a wavelength of approximately 117 nm. BeO has a hexagonal lattice structure.

It is contemplated that further work in this area will lead to a decrease in the band gap to values smaller than approximately 3.3 eV in order to fabricate semiconductor devices that can operate at long wavelengths. For simplicity of growth, it would be desirable to have an alloy system comprised of one set of elements to cover the energy band gap range from approximately 3.3 eV to an energy band gap value of approximately 1.75 eV, corresponding to a wavelength of 710 nm. The present invention enables such an alloy system.

Cadmium selenide (CdSe) has an energy band gap of approximately 1.75 eV, corresponding to a wavelength of approximately 710 nm. CdSe can be grown with a hexagonal lattice structure using proper growth conditions.

Zinc selenide (ZnSe) has an energy band gap of approximately 2.8 eV, corresponding to a wavelength of approximately 444 nm. ZnSe can be grown with a hexagonal lattice structure using proper growth conditions. ZnO, BeO, CdSe, CdO and ZnSe are Group II-VI compounds.

Collectively, the energy band gap values for ZnO based alloys comprised of the two alloy systems—ZnBeO, namely, Zn₁₋ₓBeₓO, with x varying between 0 and 1 as required, and ZnCdOSe, namely, Zn_{1-y}Cd_{y}O_{1-z}Se_{z}, with y varying between 0 and 1 as required and with z varying between 0 and 1 independently as required—would span the range from approximately 10.6 eV to approximately 1.75 eV, corresponding to a wavelength range from approximately 117 nm to approximately 710 nm.

In the following discussions, the term ZnBeO alloy is used to refer to Zn₁₋ₓBeₓO alloy, wherein the atomic fraction x of Be varies from 0 to 1, or as it may be specified.

In an alternate notation, the term ZnBeO alloy is used herein to refer to Zn₁₋ₓBeₓO alloy, wherein 0≦x≦1, or as it may be specified.

Similarly, the term ZnCdOSe alloy is used to refer to Zn_{1-y}Cd_{y}O_{1-z}Se_{z} alloy, wherein the atomic fraction y of Cd varies from 0 to 1 and the atomic fraction z of Se varies from 0 to 1, independently, as values for y and z may each be specified.

In an alternate notation, the term ZnCdOSe alloy is used herein to refer to Zn_{1-y}C d_{y}O_{1-z}Se_{z} alloy, wherein 0≦y≦1 and 0≦z≦1, independently, as values for y and z may each be specified.

The energy band gap modulated materials should have high crystalline quality so that semiconductor devices fabricated from these materials have high performance characteristics. ZnO and ZnO alloy materials that are used to fabricate semiconductor devices with high function, capability and performance require a growth process with function and capability for proper control of film growth, composition, and quality and capability for growing undoped material, p-type doped semiconductor material, and n-type semiconductor material and for growth of layers and heterostructures using these layers.

### The Applicants' HBD Technique:

In this regard, the Applicants previously developed a Hybrid Beam Deposition (HBD) process that enabled, among other aspects, the growing of p-type ZnO using an external As-molecular beam to incorporate As-dopant into the film rather than by As-diffusion. This HBD process is described in commonly-owned Patent Applications U.S. 60/406,500, PCT/US03/27143 and U.S. Ser. No. 10/525,611, filed Aug. 28, 2002, Aug. 27, 2003 and Feb. 23, 2005, respectively, each and all of which is/are hereby incorporated by reference.

The Applicants' HBD process for producing As-doped p-type ZnO films can be used to precisely control the doping level. The optical and electrical properties of ZnO:As grown by HBD are discussed in the above-cited, commonly owned patent applications incorporated herein by reference. In particular, hole carrier concentrations sufficiently high for semiconductor layers and structures and for device fabrication can be obtained. The thermal binding energy of the As-acceptor (E_{A}^{th-b}) is 129 meV, as derived from temperature-dependent Hall Effect measurements. The PL spectra reveal two different acceptor levels (E_{A}^{opt-b}), located at 115 and 164 meV, respectively, above the maximum of the ZnO valence band, and also show the binding energy of the exciton to the As-acceptor (EAXb) is about 12 meV. The quality of p-type ZnO:As layers grown by HBD are sufficiently high for device fabrication.

### The Applicants' Related Zinc Oxide Films and Structures:

The Applicants also note that wide band gap semiconductor materials have utility for device operation at high temperatures. Zinc oxide is a wide band gap material, and it also possesses good radiation resistance properties. Wide band gap semiconductor films of zinc oxide are now available in both n-type and p-type carrier types that have properties sufficient for fabrication of semiconductor devices.

By way of example, U.S. Pat. No. 6,291,085 (White et al.) discloses a p-type doped zinc oxide film, and wherein the film could be incorporated into a semiconductor device including an FET.

U.S. Pat. No. 6,342,313 (White et al.) discloses a p-type doped metal oxide film having a net acceptor concentration of at least about 10¹⁵ acceptors/cm³, wherein the film is an oxide compound of an element selected from the groups consisting of Group 2 (beryllium, magnesium, calcium, strontium, barium and radium), Group 12 (zinc, cadmium and mercury), Group 2 and 12, and Group 12 and Group 16 (oxygen, sulfur, selenium, tellurium and polonium) elements, wherein the p-type dopant is an element selected from the groups consisting of Group I (hydrogen, lithium, sodium, potassium, rubidium, cesium and francium), Group 11 (copper, silver and gold), Group 5 (vanadium, niobium and tantalum) and Group 15 (nitrogen, phosphorous, arsenic, antimony and bismuth) elements.

U.S. Pat. No. 6,410,162 (White et al.) discloses a p-type doped zinc oxide film wherein the p-type dopant is selected from Group 1, 11, 5 and 15 elements, and wherein the film can be incorporated into a semiconductor device including an FET, or into a semiconductor device as a substrate material for lattice matching to materials in the device.

The above-referenced patents and disclosures, including the above-referenced U.S. Pat. Nos. 6,291,085; 6,342,313 and 6,410,162, are incorporated by reference herein.

The Applicants' HBD process, as noted above and described in the cited, commonly owned patent documents incorporated herein by reference, enables the production of high quality semiconductor material including, but not limited to, undoped ZnO, p-type doped ZnO, n-type doped ZnO, undoped ZnBeO alloys, p-type doped ZnBeO alloys, n-type doped ZnBeO alloys, undoped ZnCdOSe alloys, p-type doped ZnCdOSe alloys, n-type doped ZnCdOSe alloys.

The Applicants also note the following additional aspects, with relevance to the present invention as described in detail below:

ZnO and BeO are Group II-VI compounds with energy band gap values of 3.3 eV and 10.6 eV, respectively. ZnO has a hexagonal crystal structure when grown under proper conditions. BeO has a hexagonal crystal structure when grown under proper conditions. From a consideration of Vemard's Law, ZnO and BeO can be mixed in a proper ratio to attain a particular energy band gap value between approximately 3.3 eV and approximately 10.6 eV. More specifically, according to Vemard's Law, the energy band gap for the alloy Zn_{0.9}Be_{0.1}O should be greater than the approximately 3.3 eV for ZnO by the amount of approximately 0.73 eV.

ZnO and CdSe are Group II-VI compounds with energy band gap values of approximately 3.3 eV and approximately 1.75 eV, respectively. CdSe has a hexagonal crystal structure when grown under proper conditions. From a consideration of Vernard's Law, ZnO and CdSe can be mixed in a proper ratio to attain a particular energy band gap value between approximately 3.3 eV and approximately 1.75 eV.

ZnO and ZnSe are Group II-VI compounds with energy band gap values of approximately 3.3 eV and approximately 2.8 eV, respectively. ZnSe has a hexagonal crystal structure when grown under proper conditions. From a consideration of Vernard's Law, ZnO and ZnSe can be mixed in a proper ratio to attain a particular energy band gap value between approximately 3.3 eV and approximately 2.8 eV.

An epitaxially layered material with an energy band gap between approximately 10.6 and approximately 3.3 eV can be designed, wherein the material can be undoped, p-type doped, or n-type doped.

An epitaxially layered material with an energy band gap between approximately 1.75 eV and approximately 3.3 eV can be designed, wherein the material can be undoped, p-type doped, or n-type doped.

The power, efficiency, function and speed of a semiconductor device is limited by the mobility of carriers, either n-type or p-type, in the semiconductor device. The availability of SL, QW and MQW structures for use in ZnO devices can be used to increase the performance, capability and function of a semiconductor device.

### EXAMPLES AND EMBODIMENTS OF THE INVENTION

With the foregoing discussion in mind, we turn to a description of embodiments and examples of the present invention.

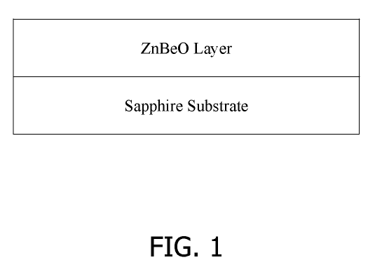

FIG. 1 illustrates an example of an embodiment of the present invention, which, in the illustrated example, comprises a layer of the semiconductor ZnBeO alloy that has been epitaxially grown on a single crystal sapphire substrate. The ZnBeO alloy layer can be doped or undoped.

ZnBeO examples: In one example in accordance with the embodiment illustrated in FIG. 1, the ZnBeO alloy has an energy band gap of approximately 4.59 eV, corresponding to a wavelength of approximately 271 nm, and is characterized by a high crystal quality suitable for use in increasing the function, capability, performance and application of a semiconductor device.

As another example in accordance with the embodiment illustrated in FIG. 1, the invention can include a ZnO based semiconductor material comprised of a ZnBeO alloy deposited on a single crystal sapphire substrate, wherein the ZnBeO alloy has an energy band gap of approximately 4.68 eV, corresponding to a wavelength of approximately 265 nm, and has a high crystal quality suitable for use in increasing the function, capability, performance and application of a semiconductor device.

As a further example, the invention can include a ZnO based semiconductor material comprised of a ZnBeO alloy deposited on a single crystal sapphire substrate, wherein the ZnBeO alloy has an energy band gap of approximately 4.86 eV, corresponding to a wavelength of approximately 256 nm, and has a high crystal quality suitable for use in increasing the function, capability, performance and application of a semiconductor device.

As yet another example, the invention provides a ZnO based semiconductor material comprised of a ZnBeO alloy deposited on a single crystal sapphire substrate, wherein the ZnBeO alloy has an energy band gap of approximately 4.96 eV, corresponding to a wavelength of approximately 250 nm, and has high crystal quality suitable for use in increasing the function, capability, performance and application of a semiconductor device.

As a further example, the invention provides a ZnO based semiconductor material comprised of a ZnBeO alloy deposited on a single crystal sapphire substrate, wherein the ZnBeO alloy has an energy band gap of approximately 5.39 eV, corresponding to a wavelength of approximately 230 nm, and has high crystal quality suitable for use in increasing the function, capability, performance and application of a semiconductor device.

The energy band gap of the alloy film of the ZnBeO embodiment of the invention can be varied from approximately 3.3 to approximately 10.6 eV, more or less, by incrementally adjusting the atomic fraction of Be from 0 to 1 in the ZnBeO alloy.

While the foregoing examples and embodiments of the present invention are described with respect to a ZnBeO alloy, it will be understood that the present invention may be practiced with respect to other ZnBeO alloys and to other types of ZnO alloys, such as (but not limited to), ZnCdOSe alloys and BeO material.

ZnCdOSe and BeO examples: By way of further example, the invention can be practiced in the form of a ZnO based semiconductor material comprised of a ZnCdOSe alloy deposited on a single crystal sapphire substrate, wherein the ZnCdOSe alloy has high crystal quality suitable for use in increasing the function, capability, performance and application of a semiconductor device.

The energy band gap value of the ZnCdOSe alloy film of the invention can be varied from approximately 3.3 eV to approximately 1.75 eV, more or less, by adjusting independently the atomic fraction of Cd and the atomic fraction of Se from 0 to 1 in the ZnCdOSe alloy.

In addition, the energy band gap of the ZnBeO alloy film of the invention can be made to be approximately 10.6 eV, more or less, by growing BeO.

In accordance with a further aspect of the invention, the ZnBeO alloy, ZnCdOSe alloy and BeO can be used, individually or in various combinations, or in various combinations with ZnO or other semiconductor materials, to form useful layers and structures, including, but not limited to, semiconductor heterostructures, active layers, quantum wells, multiple quantum wells, superlattice layers, isolation layers, light reflecting films and multilayers, metal contact layers, cladding layers, Schottky barriers and substrates; can be used to fabricate semiconductor devices; and can be used to increase the function, capability, performance and application of a semiconductor device.

Those skilled in the art will appreciate that in accordance with the invention, and analogous to the example of FIG. 1, many variations are possible and are within the scope of the invention. Such variations can include, by way of example, any or combinations of the following:
a layer of the semiconductor ZnBeO alloy can be epitaxially grown on a material or substrate material of composition different from a single crystal sapphire substrate;
a layer of ZnBeO alloy can be grown that is p-type or n-type doped semiconductor material;
a layer of ZnCdOSe can be epitaxially grown on a single crystal sapphire substrate;
a layer of semiconductor ZnCdOSe can be epitaxially grown on a material or substrate material of composition different from a single crystal sapphire substrate;
a layer of ZnCdOSe alloy can be grown that is undoped; or p-type or n-type doped semiconductor material;
a layer of semiconductor BeO material can be epitaxially grown upon a material or substrate material of composition different from a single crystal sapphire substrate;
a layer of BeO material can be grown that is undoped, p-type or n-type doped semiconductor material;
n-type ZnBeO semiconductor alloy material can be prepared wherein the n-type dopant is an element, or more than one element, selected from the group consisting of boron, aluminum, gallium, indium, thallium, fluorine, chlorine, bromine and iodine;
p-type ZnBeO semiconductor alloy material can be prepared wherein the p-type dopant is an element, or more than one element, selected from the Group 1, 11, 5 and 15 elements;
p-type ZnBeO semiconductor alloy material can be prepared wherein the p-type dopant is selected from the group consisting of arsenic, phosphorus, antimony and nitrogen;
p-type ZnBeO semiconductor alloy material can be prepared wherein the p-type dopant is arsenic;
n-type ZnCdOSe semiconductor alloy material can be prepared wherein the n-type dopant is an element, or more than one element, selected from the group consisting of boron, aluminum, gallium, indium, thallium, fluorine, chlorine, bromine and iodine;
the p-type ZnCdOSe semiconductor alloy material can be prepared wherein the p-type dopant is an element, or more than one element, selected from the Group 1, 11, 5 and 15 elements;
the p-type ZnCdOSe semiconductor alloy material can be prepared wherein the p-type dopant is selected from the group consisting of arsenic, phosphorus, antimony and nitrogen.
the p-type ZnCdOSe semiconductor alloy material can be prepared wherein the p-type dopant is arsenic.
ZnBeO semiconductor material can be grown with an atomic fraction of Mg incorporated into the ZnBeO material for applications to form lattice matched layers wherein the ZnBeO film can be either undoped, p-type doped, or n-type doped semiconductor material;
n-type BeO semiconductor material can be prepared wherein the n-type dopant is an element, or more than one element, selected from the group consisting of boron, aluminum, gallium, indium, thallium, fluorine, chlorine, bromine and iodine;
p-type BeO semiconductor material can be prepared wherein the p-type dopant is an element, or more than one element, selected from Group 1, 11, 5 and/or 15 elements;
the p-type BeO semiconductor material can be prepared wherein the p-type dopant is selected from the group consisting of arsenic, phosphorus, antimony and nitrogen; and/or
the p-type BeO semiconductor material can be prepared wherein the p-type dopant is arsenic.

### EXAMPLE OF MANUFACTURE

In one such example, a polished sapphire wafer cut from a bulk crystal was used as the substrate. The wafer was placed in a hybrid beam deposition reactor, and heated to approximately 750° C. The pressure was reduced to approximately 1×10⁵ Torr and the substrate cleaned with an RF oxygen plasma for 30 minutes. The temperature was then lowered to 650° C. and then a layer of ZnBeO was deposited to a thickness of approximately 0.3 microns on the substrate. During the deposition of the ZeBeO semiconductor alloy a thermally controlled Knudsen cell containing Be was heated to produce a beam of Be vapor that impinged on the substrate simultaneous with the beams used to grow ZnO.

(A more detailed description of exemplary hybrid beam deposition (HBD) processes for depositing a zinc oxide layer, an n-type zinc oxide layer, and a p-type zinc oxide layer, and in particular a p-type zinc oxide layer doped with arsenic, is set forth in one or more of commonly owned U.S. Pat. Nos. 6,475,825 and 6,610,141, and Patent Applications U.S. 60/406,500, PCT/US03/27143 and U.S. Ser. No. 10/525,611, each and all of which is/are hereby incorporated by reference as if set forth in their entireties herein.)

The wafer with deposited layer was then removed from the reactor and placed in a visible-ultraviolet transmission spectrometer that had a lower cutoff wavelength limit of approximately 180 nm. The ZnBeO semiconductor alloy film was characterized at room temperature using optical transmission measurements to determine the transmittance versus wavelength.

Transmittance vs. Wavelength Data:

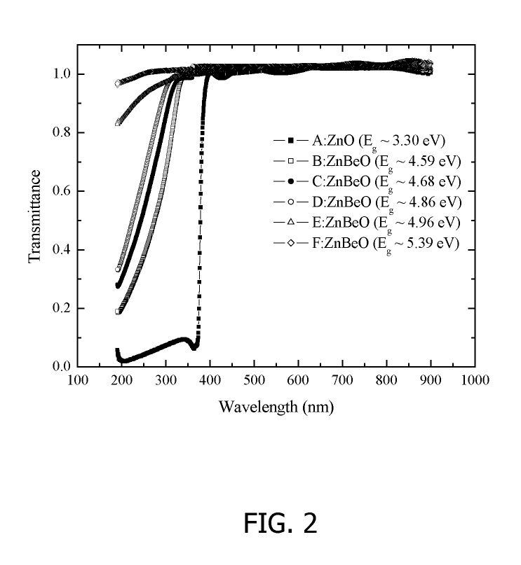

FIG. 2 shows data for examples of a ZnBeO embodiment of the invention, with transmittance plotted versus wavelength of light incident on the ZnBeO alloy films, and also for a ZnO film. The atomic fraction of Be is zero for the ZnO film labeled as curve A. The atomic fraction of Be increases monotonically as determined by film growth conditions in proceeding from curve A to B, to C, to D, to E and to F so that the curve labeled F shows data for a film that has the highest atomic fraction of Be of those shown. (The lower wavelength limit capability of the spectrometer is approximately 180 nm.)

The use of the label ZnBeO in the legend in FIG. 2 pertains to ZnBeO alloys that contain some atomic fraction of Be that may differ from the atomic fraction of Zn in a particular alloy.

In accordance with the invention, a fit to the data analysis can be made for each of the optical transmission measurement curves to determine a value for the energy band gap for ZnO (transmission curve A) and the energy band gap value for each of the ZnBeO semiconductor alloys (transmission curves B, C, D, E and F).

For transmission curve A, the energy band gap value is approximately 3.3 eV, corresponding to a wavelength of approximately 376 nm. This energy band gap value is reasonable for ZnO.

For transmission curve B, the energy band gap value is approximately 4.59 eV, corresponding to a wavelength of approximately 271 nm. This energy band gap value is reasonable for a ZnBeO alloy with some atomic fraction of Be.

For transmission curve C, the energy band gap value is approximately 4.68 eV, corresponding to a wavelength of approximately 265 nm. These values are reasonable for a ZnBeO alloy with an atomic fraction of Be greater than for that associated with transmission curve B but less than that associated with transmission curve D.

For transmission curve D, the energy band gap value is approximately 4.86 eV, corresponding to a wavelength of approximately 256 nm. This energy band gap value is reasonable for a ZnBeO alloy with an atomic fraction of Be greater than for that associated with transmission curve C but less than that associated with transmission curve F.

For transmission curve E, the energy band gap value is approximately 4.96 eV, corresponding to a wavelength of approximately 250 nm. This energy band gap value is reasonable for a ZnBeO alloy with an atomic fraction of Be greater than for that associated with transmission curve D but less than that associated with transmission curve E.

For transmission curve F, the energy band gap value is approximately 5.39 eV, corresponding to a wavelength of approximately 230 nm. This energy band gap value is reasonable for a ZnBeO alloy with an atomic fraction of Be greater than for that associated with transmission curve D.

### FURTHER EXAMPLES AND VARIATIONS OF THE INVENTION

In accordance with the invention, a ZnBeO semiconductor material can be grown with the atomic fraction of Be to be any desirable value between those associated with transmission curves A through F.

Also in accordance with the invention, ZnBeO, ZnCdOSe or BeO semiconductor materials can be grown with, in the case of ZnBeO or ZnCdOSe, respectively, the atomic fraction of Be or Cd and Se to be any desirable value between 0 and 1; wherein the ZnBeO or ZnCdOSe semiconductor material is undoped, p-type or n-type doped, grown on materials or substrates including, but not limited to, ZnO, GaN, and SiC, and is of sufficient crystal quality to be used to fabricate semiconductor structures and devices.

In accordance with the invention, ZnBeO semiconductor alloys, ZnCdOSe semiconductor alloys, and BeO semiconductor material, including undoped, p-type doped, and n-type doped semiconductor material, can be used, separately or in various combinations, or in various combinations with ZnO or other semiconductor materials, to form layers and structures including, but not limited to, semiconductor heterostructures, active layers, quantum wells, multiple quantum wells, superlattice layers, isolation layers, light reflecting films and multilayers, metal contact layers, cladding layers, Schottky barriers, and substrates; to fabricate semiconductor devices; and to increase the function, capability, performance and application of semiconductor devices.

Also in accordance with the present invention, the layers and structures that can be formed with ZnBeO semiconductor alloys, ZnCdOSe semiconductor alloys, and/or BeO semiconductor material, including undoped, p-type doped, and n-type doped semiconductor material, can be used for fabricating photonic and electronic semiconductor devices for use in photonic and electronic applications.

Uses for such devices include, but are not limited to, devices such as LEDs, LDs, FETs, PN junctions, PIN junctions, Schottky barrier diodes, UV detectors and transmitters, transistors and transparent transistors, which can be employed in applications such as light emitting displays, transistors and transparent transistors, backlighting for displays, UV and visible transmitters and detectors, high frequency radar, biomedical imaging, chemical compound identification, molecular identification and structure, gas sensors, imaging systems, and fundamental studies of atoms, molecules, gases, vapors and solids.

In accordance with the invention, ZnBeO and ZnCdOSe semiconductor materials can be employed to fabricate LEDs and LDs that have one or a multiplicity of emission wavelengths in the spectral range from approximately 117 nm to approximately 710 nm; and BeO semiconductor material can be used to fabricate LEDs and LDs that have an emission wavelength of approximately 117 nm.

Further in accordance with the invention, a ZnBeO or BeO semiconductor material can be grown with an atomic fraction of Mg incorporated therein during growth, for use in applications to form lattice matched layers, wherein the ZnBeO or BeO material containing Mg may be undoped, p-type or n-type doped semiconductor material.

The materials, layers and structures described herein can be incorporated into semiconductor devices for improvement in performance, function and capability and speed of such devices.

Those skilled in the art will appreciate that various modifications, additions and other changes can be made in the materials, layers, structures and implementations described herein, and that various modifications are possible within the spirit and scope of the invention as claimed. The terms and expressions used herein are terms of description and not of limitation, and there is no intention in the use of such terms and expressions to exclude equivalents of the features shown and described, or portions thereof. In addition, any one or more features and aspects of the invention can be combined with one or more other features of the invention, without departing from the spirit and scope of the invention, which is limited solely by the appended claims.

1. A semiconductor material or structure, comprising:
ZnBeO or ZnCdOSe semiconductor alloy materials with energy band gap values between approximately 1.75 eV and approximately 10.6 eV,
wherein selected energy band gap values are attained by selecting alloy composition,
wherein a selected atomic fraction of any of Zn, Be, Cd or Se is selected to attain the energy band gap values, and
wherein the semiconductor material or structure comprises a crystalline layer having a crystal quality sufficiently high to fabricate semiconductor materials or structures.

2. A semiconductor material or structure, comprising:
ZnBeO semiconductor alloy materials with energy band gap values between approximately 3.3 eV and approximately 10.6 eV,
wherein selected energy band gap values are attained by selecting alloy composition,
wherein a selected atomic fraction of any of Zn or Be is selected to attain the energy band gap values, and
wherein the semiconductor material or structure comprises a crystalline layer having a crystal quality sufficiently high to fabricate semiconductor materials or structures.

3. A semiconductor material or structure, comprising:
ZnBeO or ZnCdOSe semiconductor alloy materials that are undoped, with energy band gap values between approximately 1.75 eV and approximately 10.6 eV,
wherein selected energy band gap values are attained by selecting alloy composition,
wherein a selected atomic fraction of any of Zn, Be, Cd or Se is selected to attain the energy band gap values, and
wherein the semiconductor material or structure comprises a crystalline layer having a crystal quality sufficiently high to fabricate semiconductor materials or structures.

4. A semiconductor material or structure, comprising:
ZnBeO semiconductor alloy materials that are undoped, with energy band gap values between approximately 3.3 eV and approximately 10.6 eV,
wherein selected energy band gap values are attained by selecting alloy composition,
wherein a selected atomic fraction of Be or Zn is selected to attain the energy band gap values, and
wherein the semiconductor material or structure comprises a crystalline layer having a crystal quality sufficiently high to fabricate semiconductor materials or structures.

5. A semiconductor material or structure, comprising:
ZnBeO or ZnCdOSe semiconductor alloy materials that are p-type doped, with energy band gap values between approximately 1.75 eV and approximately 10.6 eV,
wherein selected energy band gap values are attained by selecting alloy composition,
wherein a selected atomic fraction of any of Zn, Be, Cd or Se is selected to attain the energy band gap values, and
wherein the semiconductor material or structure comprises a crystalline layer having a crystal quality sufficiently high to fabricate semiconductor materials or structures.

6. A semiconductor material or structure, comprising:
ZnBeO semiconductor alloy materials that are p-type doped, with energy band gap values between approximately 3.3 eV and approximately 10.6 eV,
wherein selected energy band gap values are attained by selecting alloy composition,
wherein a selected atomic fraction of any of Zn or Be is selected to attain the energy band gap values, and
wherein the semiconductor material or structure comprises a crystalline layer having a crystal quality sufficiently high to fabricate semiconductor materials or structures.

7. A semiconductor material or structure, comprising:
ZnBeO or ZnCdOSe semiconductor alloy materials that are n-type doped, with energy band gap values between approximately 1.75 eV and approximately 10.6 eV,
wherein selected energy band gap values are attained by selecting alloy composition,
wherein a selected atomic fraction of any of Zn, Be, Cd or Se is selected to attain the energy band gap values, and
wherein the semiconductor material or structure comprises a crystalline layer having a crystal quality sufficiently high to fabricate semiconductor materials or structures.

8. A semiconductor material or structure, comprising:
ZnBeO semiconductor alloy materials that are n-type doped, with energy band gap values between approximately 3.3 eV and approximately 10.6 eV,
wherein selected energy band gap values are attained by selecting alloy composition,
wherein a selected atomic fraction of any of Zn or Be is selected to attain the energy band gap values, and
wherein the semiconductor material or structure comprises a crystalline layer having a crystal quality sufficiently high to fabricate semiconductor materials or structures.

9. A semiconductor material or structure, comprising:
ZnBeO or ZnCdOSe semiconductor alloy materials that are p-type doped, comprising a crystalline layer having a crystal quality sufficiently high to fabricate semiconductor materials or devices, with energy band gap values between approximately 1.75 eV and approximately 10.6 eV,
wherein selected energy band gap values are attained by selecting alloy composition,
wherein a selected atomic fraction of any of Zn, Be, Cd or Se is selected to attain the energy band gap values, and
wherein dopant for the p-type zinc oxide semiconductor alloy materials is at least one element selected from Group 1, 11, 5, and 15 elements.

10. A semiconductor material or structure, comprising:
ZnBeO semiconductor alloy materials that are p-type doped, comprising a crystalline layer having a crystal quality sufficiently high to fabricate semiconductor materials or devices, with energy band gap values between approximately 3.3 eV and approximately 10.6 eV,
wherein selected energy band gap values are attained by selecting alloy composition,
wherein a selected atomic fraction of any of Zn or Be is selected to attain the energy band gap values, and
wherein dopant for the p-type zinc oxide semiconductor alloy materials is at least one element selected from Group 1, 11, 5, and 15 elements.

11. A semiconductor material or structure, comprising:
ZnBeO or ZnCdOSe semiconductor alloy materials that are p-type doped, comprising a crystalline layer having a crystal quality sufficiently high to fabricate semiconductor materials or devices, with energy band gap values between approximately 1.75 eV and approximately 10.6 eV,
wherein selected energy band gap values are attained by selecting alloy composition,
wherein a selected atomic fraction of any of Zn, Be, Cd or Se is selected to attain the energy band gap values, and
wherein dopant for the p-type ZnBeO or ZnCdOSe semiconductor alloy materials is at least one element selected from the group consisting of arsenic, phosphorus, antimony and nitrogen.

12. A semiconductor material or structure, comprising:
ZnBeO semiconductor alloy materials that are p-type doped, comprising a crystalline layer having a crystal quality sufficiently high to fabricate semiconductor materials or devices, with energy band gap values between approximately 3.3 eV and approximately 10.6 eV,
wherein selected energy band gap values are attained by selecting alloy composition,
wherein a selected atomic fraction of any of Zn or Be is selected to attain the energy band gap values, and
wherein dopant for the p-type ZnBeO semiconductor alloy materials is at least one element selected from the group consisting of arsenic, phosphorus, antimony and nitrogen.

13. The semiconductor material or structure of claim 1, wherein the semiconductor material or structure is produced by a hybrid beam deposition process.

14. The semiconductor material or structure of claim 2, wherein the semiconductor material or structure is produced by a hybrid beam deposition process.

15. The semiconductor material or structure of claim 3, wherein the semiconductor material or structure is produced by a hybrid beam deposition process.

16. The semiconductor material or structure of claim 4, wherein the semiconductor material or structure is produced by a hybrid beam deposition process.
